(19) United States
(12) Patent Application Publication
(10) Pub. No.: US 2026/0096025 A1
(43) Pub. Date: Apr. 2, 2026

(54) SUBSTRATE WITH HINGE

(71) Applicant: SMART Modular Technologies, Inc., Newark, CA (US)

(72) Inventors: Kwang Jin Gooi, Pulau Pinang (MY); Muhammad Annuar Bin Johani, Pulau Pinang (MY); Ali Akbar Bin Abdul Aziz, Pulau Pinang (MY); Satyanarayan Iyer, Fremont, CA (US)

(21) Appl. No.: 18/904,279

(22) Filed: Oct. 2, 2024

(51) Int. Cl. H05K 1/14

(52) U.S. Cl. CPC H05K 1/148

(57) ABSTRACT

A substrate with a hinge is disclosed. In one aspect, the substrate may be a printed circuit board (PCB) or the like with a socket configured to receive a memory module, such as a dual inline memory module (DIMM). The substrate further includes a hinge that allows the portion of the substrate with the socket to rotate ninety (90) degrees so that a memory module inserted into the socket is then parallel to the other portion of the substrate. By allowing the memory module to be so positioned, the overall shape and configuration of a module using the substrate may fit a smaller form factor.

### BACKGROUND

### I. Field of the Disclosure

The technology of the disclosure relates generally to a substrate such as a printed circuit board (PCB) with a hinge to facilitate shape adjustments.

### II. Background

Computing devices abound in modern society. The prevalence of these computing devices is driven in part by the many functions that are now enabled on such devices. With the myriad functions, there has been a demand for increased processing capabilities. Such processing capabilities, seemingly invariable, also create demands for more memory. For example, an early APPLE computer came with 48KB of memory. Contemporary MacBooks may have over 32GB of memory readily available. For higher-end operations such as machine learning, data mining, or the like, memory demands may be exceptionally high. While memory sizes have decreased over time, such size decreases have not kept pace with the demands for more memory. Further, while it is possible to increase the overall size of a computing device to accommodate more memory, commercial pressures dictate that the size of the computing device remain steady or even decrease. Accordingly, there is room for innovation in fitting memory devices into a computing device.

### SUMMARY

Aspects disclosed in the detailed description include a substrate with a hinge. In particular, the substrate may be a printed circuit board (PCB) or the like with a socket configured to receive a memory module, such as a dual inline memory module (DIMM). The substrate further includes a hinge that allows the portion of the substrate with the socket to rotate ninety (90) degrees so that a memory module inserted into the socket is then parallel to the other portion of the substrate. By allowing the memory module to be so positioned, the overall shape and configuration of a module using the substrate may fit a smaller form factor.

In this regard, in one aspect, an add-in card is disclosed. The add-in card includes a first portion comprising a contact blade and a second portion comprising a socket configured to fit a memory module. The add-in card also includes a flexible portion electrically coupling contacts of the contact blade to the socket and a hinge rotationally coupling the first portion to the second portion such that the second portion may rotate between a first position parallel to the first portion to a second position perpendicular to the first portion.

In another aspect, a method of using an add-in card is disclosed. The method includes inserting a memory module into a socket on a second portion of the add-in card, rotating the second portion of the add-in card relative to a first portion between a parallel first position to a perpendicular second position, and securing the first portion relative to the second portion.

In another aspect, a computing device is disclosed. The computing device includes a motherboard comprising a first socket and an add-in card. The add-in card comprises a first portion comprising a contact blade inserted into the first socket, a second portion comprising a socket configured to fit a memory module, a flexible portion electrically coupling contacts of the contact blade to the socket, and a hinge rotationally coupling the first portion to the second portion such that the second portion may rotate between a first position parallel to the first portion to a second position perpendicular to the first portion. The computing device further includes a memory module.

### BRIEF DESCRIPTION OF THE DRAWINGS

FIG. 1 is an end-on view of a conventional module with a substrate having a socket for a memory module placed perpendicular to the substrate;

FIG. 2 is a top-plan view of a substrate with a hinge according to exemplary aspects of the present disclosure;

FIGS. 3A &3B are side and top views of the hinge of the present disclosure removed from the substrate;

FIGS. 4A-4C illustrate an end on view of the substrate of FIG. 2 with the hinge in various positions to illustrate its operation;

FIG. 5 is an end-on view of a module with a substrate with a hinge according to aspects of the present disclosure highlighting how the form factor changes when the hinge is used;

FIG. 6 is a flowchart illustrating an exemplary process for using the substrate of FIG. 2; and

FIG. 7 is a block diagram of a computing device, which may include the substrate of FIGS. 2-5 according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element, or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a," “an,” and “the” are intended to include the plural forms as well unless the context clearly indicates otherwise. It will be further understood that the terms “comprises," “comprising," “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

To the extent that the term “approximately” is used in the claims, it is herein defined to be within five percent (5%).

Aspects disclosed in the detailed description include a substrate with a hinge. In particular, the substrate may be a printed circuit board (PCB) or the like with a socket configured to receive a memory module, such as a dual inline memory module (DIMM). The substrate further includes a hinge that allows the portion of the substrate with the socket to rotate ninety (90) degrees so that a memory module inserted into the socket is then parallel to the other portion of the substrate. By allowing the memory module to be so positioned, the overall shape and configuration of a module using the substrate may fit a smaller form factor.

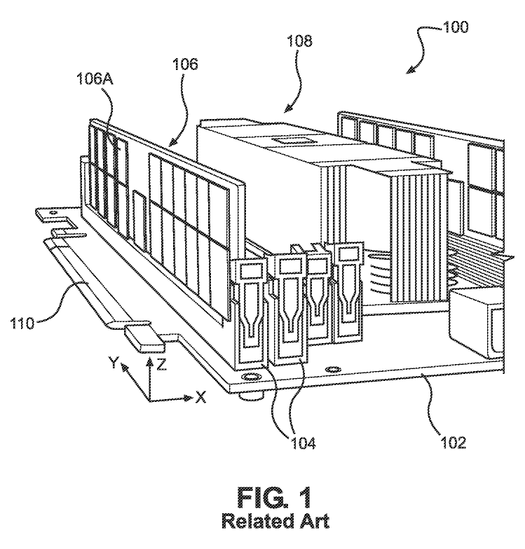

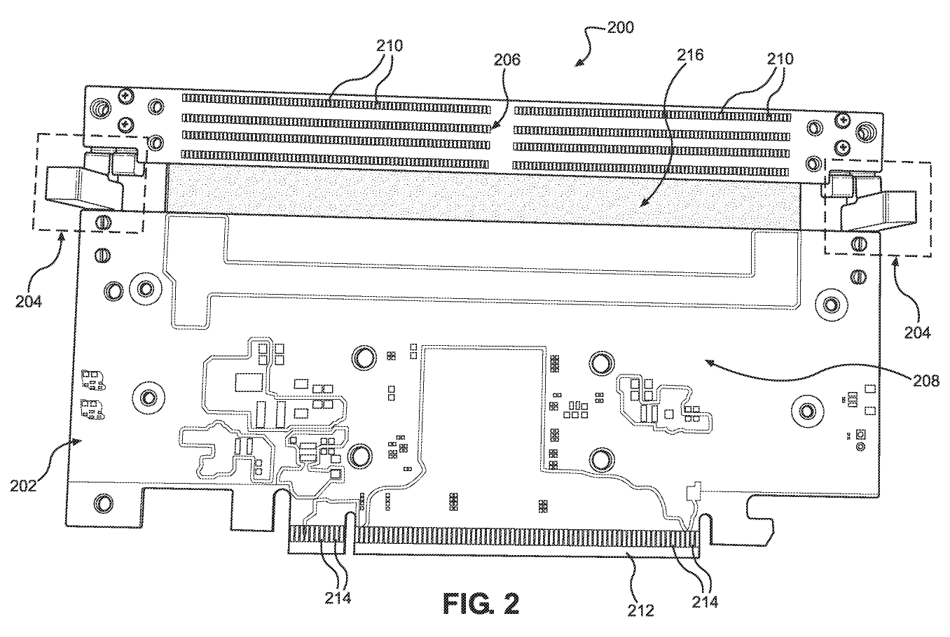

Before addressing aspects of the present disclosure, a brief overview of a conventional module having a rigid substrate is provided with reference to FIG. 1. A discussion of aspects of the present disclosure begins below with reference to FIG. 2.

In this regard, FIG. 1 illustrates an add-in card 100 that includes a substrate 102 that is substantially rigid. Sockets 104 may be positioned on the substrate 102 to hold memory modules 106 (only one illustrated and sometimes called memory cards). The memory modules 106 may include memory chips 106A thereon. The memory modules 106 are perpendicular to an x-y plane formed by the substrate 102. As illustrated, the add-in card 100 may be a graphics card or the like with a processor and heat sink assembly 108 as well as other circuits (not labeled). The add-in card 100 may include a contact blade 110 that provides communicative connections to contacts in another socket (not shown), such as on a motherboard or the like.

In some instances, a computing device may have multiple add-in cards 100 installed therein. For example, a server blade in a server farm being used to run a complex machine learning algorithm may have multiple add-in cards 100 with abundant memory to assist in performing the complex calculations associated with the machine learning algorithm. In such instances, the add-in card 100 must fit within a predefined form factor. For example, the add-in card 100 may have a z-axis dimension of approximately 35 mm. Commercial pressure to reduce this dimension requires either expanding the x or y dimension or reducing the amount of memory chips 106A. As memory demands continue to increase, reducing the number of memory chips 106A is not a practical solution. Likewise, increasing the x-y dimensions is also contraindicated by the general desire to reduce the form factor for the add-in cards used in such situations.

Aspects of the present disclosure allow adjustments to the dimensions of a substrate by introducing a hinge that allows a first or movable portion of the substrate to be perpendicular to a second or fixed portion of the substrate. In exemplary aspects, the movable portion includes one or more sockets for memory modules such that the memory modules are parallel to the fixed portion when the first portion is rotated around the hinge. Use of this hinge allows the x, y, and z dimensions of the resultant add-in card to be smaller than conventional approaches.

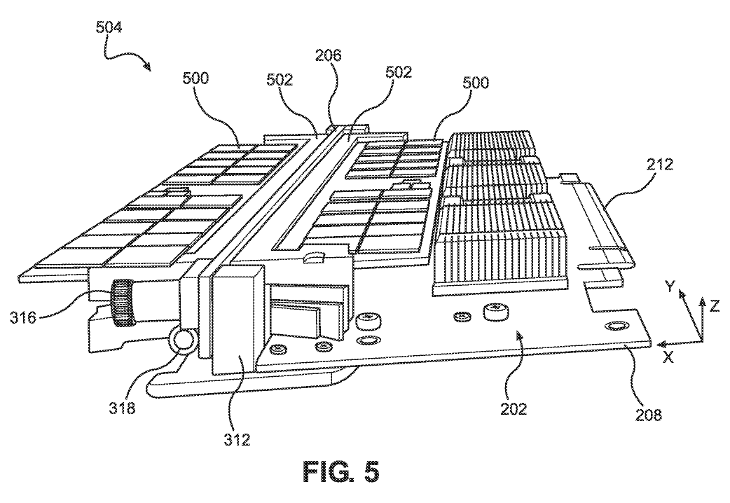

In this regard, FIG. 2 illustrates an add-in card 200 having a substrate 202 with a hinge 204 according to aspects of the present disclosure. The substrate 202 has a first or movable portion 206 and a second or fixed portion 208. The first portion 206, has contacts 210, which are configured to work with one or more sockets 502 (seen in FIG. 5) to hold memory modules 500 (again seen in FIG. 5) that have been removed in FIG. 2 to avoid cluttering FIG. 2. The second portion 208 may have a contact blade 212 with contacts 214 thereon that are configured to work with another socket (not shown), such as may be on a motherboard or the like. The substrate 202 may be a PCB or the like and is generally substantially rigid except at flexible portion 216. The flexible portion 216 may be a polyimide film and/or a polyester film and/or a polyethylene naphthalate material with conductors therein, such as those sold by Molex of Lisle Illinois in their flexible printed circuits (FPC) product line.

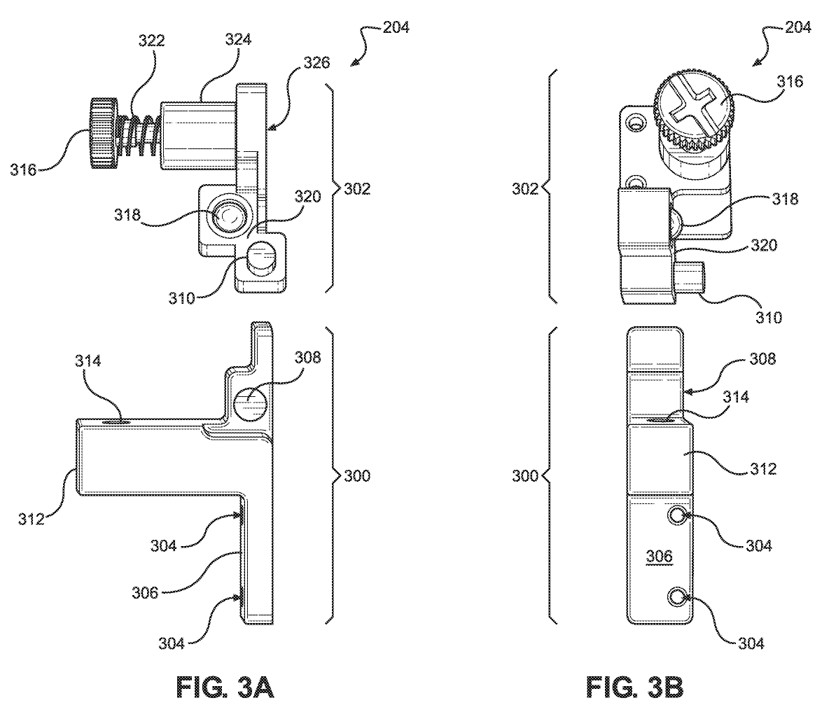

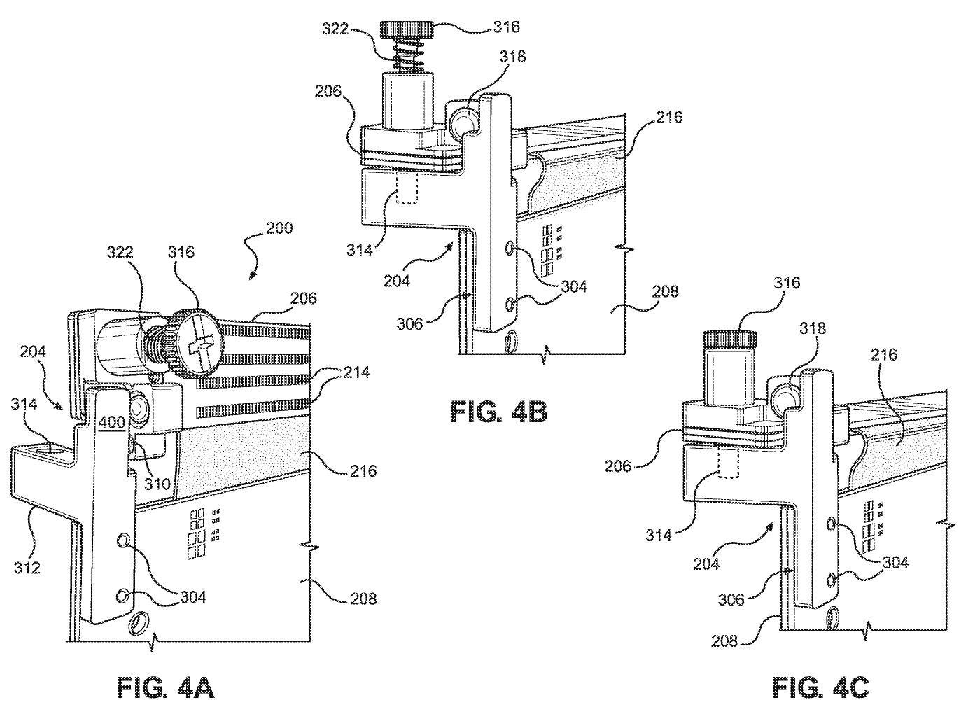

FIGS. 3A & 3B provide additional details about the hinge 204. In particular, the hinge 204 may include a fixed part 300 and a rotating part 302. The fixed part 300 is designed to mount on the second portion 208, such as through screws (not shown), which may pass through mounting holes 304. To assist in this mounting, the fixed part 300 includes a planar surface 306, which lies flush against the second portion 208. An axle socket 308 is provided to receive an axle 310 on the rotating part 302. A capture body 312 is also provided on the fixed part 300. The capture body 312 includes a threaded channel 314 that interoperates with a captive screw 316 on the rotating part 302. The rotating part 302 also includes a spring plunger 318 that, when an interior spring (not shown) is at rest, causes a protuberance or bump of the plunger 318 to extend from a surface 320 of the rotating part 302. Manual manipulation or the like can compress the spring, pushing the bump into the rotating part 302, allowing rotation about the axle 310. However, when not pushed in, the bump of the plunger 318 will inhibit rotation. The captive screw 316 more securely inhibits rotation, as better illustrated in FIGS. 4A-4C but includes a spring 322 that initially causes the captive screw 316 to be biased away from shaft 324 and keeps the captive screw 316 from extending past a surface 326.

FIGS. 4A-4C show how the spring plunger 318 and captive screw 316 work to keep the rotating part 302/first portion 206 in a desired position. That is, in FIG. 4A, the first portion 206 is substantially parallel to the second portion 208. The relative positions are maintained by the plunger 318, which protrudes slightly so that rotation about the axle 310 is inhibited where the plunger 318 contacts surface 400. The spring 322 keeps the captive screw 316 elevated.

On depression of the plunger 318, the first portion 206 may rotate 90 degrees until the first portion 206 comes into contact with the capture body 312 (as shown in FIG. 4B). Capture body 312 prevents over-rotation. Note that plunger 318 returns to its extended position, although plunger 318 is relatively inconsequential unless counter-rotation is desired at some future time when the plunger 318 may need to be depressed to allow such counter-rotation.

Once the first portion 206 is in the rotated position, the captive screw 316 may be pushed against the spring 322 and rotated such that the threads of the captive screw 316 engage the threads inside the threaded channel 314. As the captive screw 316 is threaded into the channel 314, the spring 322 will compress, but as shown in FIG. 4C, the captive screw 316 will keep the first portion 206 in a fixed position, ninety degrees or perpendicular to the second portion 208. By keeping the first portion 206 and the second portion 208 fixed relative to one another, new stresses are not introduced to the flexible portion 216.

As better illustrated in FIG. 5, once the memory modules 500 are inserted in the sockets 502 and the first portion 206 rotated into the perpendicular position, the overall height (in the z-axis) of an add-in card 504 may be substantially reduced relative to the add-in card 100. Note also, the first portion 206 may have sockets 502 on both sides so that the memory modules 500 extend like wings on either side of the first portion 206.

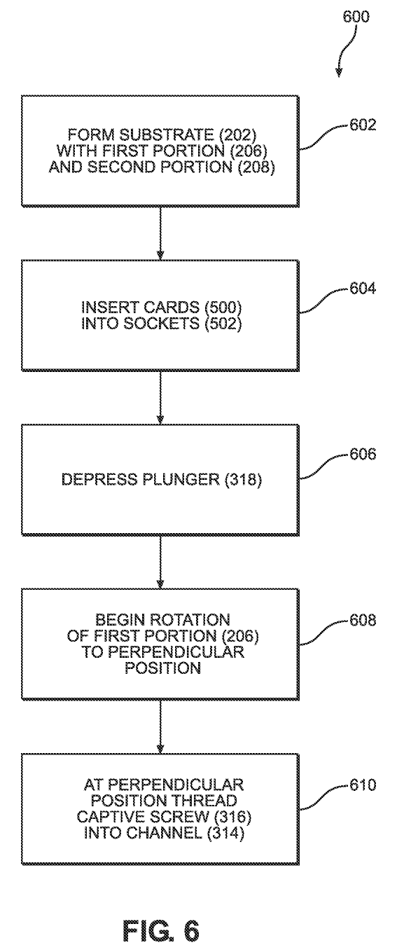

FIG. 6 is a flowchart of a process 600 for installing memory in a computing device using the add-in card 200 of the present disclosure. In this regard, the process 600 begins by forming the substrate 202 with first portion 206 and second portion 208 (block 602) coupled by hinge 204 and the flexible portion 212. Memory modules 500 are inserted in the sockets 502 on the first portion 206 (block 604). The plunger 318 is then pressed (block 606) to allow the first portion 206 to begin rotation to the perpendicular position (block 608). Once at the perpendicular position, the captive screw 316 is threaded into the channel 314 (block 610) to secure the first portion 206 in the final position. Note that the modules may be inserted after block 610 instead of before rotation.

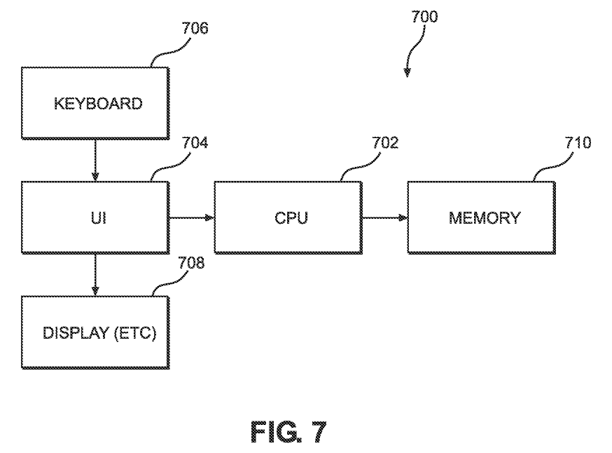

FIG. 7 illustrates a block diagram of a computing device 700 that may have the add-in card 200 with memory modules 500 therein. In particular, a central processing unit (CPU) 702 may communicate with a user interface (U/I) 704 that includes a keyboard 706 and mouse 708 (or other input/output devices). The CPU 702 may also interoperate with a memory 710 that may include memory modules 500 mounted in the add-in card 200 of the present disclosure.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. An add-in card comprising:
a first portion comprising a contact blade;
a second portion comprising a socket configured to fit a memory module;
a flexible portion electrically coupling contacts of the contact blade to the socket; and
a hinge rotationally coupling the first portion to the second portion such that the second portion may rotate between a first position parallel to the first portion to a second position perpendicular to the first portion.

2. The add-in card of claim 1, wherein the socket is positioned on the second portion such that the socket is perpendicular to the first portion when the first portion is parallel to the second portion.

3. The add-in card of claim 2, wherein the socket is parallel to the first portion when the first portion is perpendicular to the second portion.

4. The add-in card of claim 1, further comprising second through fourth sockets, wherein the second socket is positioned on the second portion on a side opposite the third socket.

5. The add-in card of claim 1, wherein the first portion and the second portion each comprise a substrate.

6. The add-in card of claim 5, wherein the substrate comprises a printed circuit board (PCB).

7. The add-in card of claim 1, wherein the socket is sized to accommodate a dual inline memory module (DIMM) card.

8. The add-in card of claim 1, further comprising a circuit positioned on the first portion.

9. The add-in card of claim 1, wherein the hinge comprises a fixed part and a rotating part, wherein the rotating part rotates around a hinge on the fixed part.

10. The add-in card of claim 9, wherein the fixed part comprises a capture body comprising a threaded channel and configured to stop rotation of the rotating part.

11. The add-in card of claim 10, wherein the rotating part comprises a captive screw configured to thread into the threaded channel.

12. The add-in card of claim 10, wherein the rotating part comprises a spring plunger configured to hold the hinge in the first position.

13. A method of using an add-in card, comprising:
inserting a memory module into a socket on a second portion of the add-in card;
rotating the second portion of the add-in card relative to a first portion between a parallel first position to a perpendicular second position; and
securing the first portion relative to the second portion.

14. The method of claim 13, wherein securing the first portion comprises using a captive screw and a threaded channel.

15. The method of claim 13, further comprising compressing a spring plunger before rotating.

16. A computing device comprising:
a motherboard comprising a first socket;
an add-in card comprising:
a first portion comprising a contact blade inserted into the first socket;
a second portion comprising a socket configured to fit a memory module;
a flexible portion electrically coupling contacts of the contact blade to the socket; and
a hinge rotationally coupling the first portion to the second portion such that the second portion may rotate between a first position parallel to the first portion to a second position perpendicular to the first portion; and
the memory module.
